(19) United States
(12) Patent Application Publication
(10) Pub. No.: US 2025/0248115 A1
(43) Pub. Date: Jul. 31, 2025

(54) HIGH VOLTAGE CMOS DEVICE AND MANUFACTURING METHOD THEREOF

(71) Applicant: Richtek Technology Corporation, Zhubei City (TW)

(72) Inventors: Wu-Te Weng, Hsinchu (TW); Chih-Wen Hsiung, Hsinchu (TW); Ta-Yung Yang, Taoyuan (TW)

(21) Appl. No.: 19/069,295

(22) Filed: Mar. 4, 2025

Related U.S. Application Data
(62) Division of application No. 18/052,062, filed on Nov. 2, 2022.
(60) Provisional application No. 63/264,773, filed on Dec. 1, 2021.

(30) Foreign Application Priority Data
Apr. 19, 2022 (TW) 111114904

(51) Int. Cl. H10D 84/85; H10D 30/01; H10D 30/65; H10D 84/01; H10D 84/03

(52) U.S. Cl. CPC H10D 84/859; H10D 30/0281; H10D 30/65; H10D 84/0188; H10D 84/038

(57) ABSTRACT

A high voltage complementary metal oxide semiconductor (CMOS) device includes: a semiconductor layer, plural insulation regions, a first N-type high voltage well and a second N-type high voltage well, which are formed by one same ion implantation process, a first P-type high voltage well and a second P-type high voltage well, which are formed by one same ion implantation process, a first drift oxide region and a second oxide region, which are formed by one same etching process by etching a drift oxide layer; a first gate and a second gate, which are formed by one same etching process by etching a polysilicon layer, an N-type source and an N-type drain, and a P-type source and a P-type drain.

### CROSS REFERENCE

This application is a divisional application of U.S. patent application Ser. No. 18/052,062.

### BACKGROUND OF THE INVENTION

### Field of Invention

The present invention relates to a high voltage complementary metal oxide semiconductor (CMOS) device and a manufacturing method thereof; particularly, it relates to a high voltage CMOS device integrating an N-type high voltage device and a P-type high voltage device therein and a manufacturing method thereof.

### Description of Related Art

High voltage devices are used in power management integrated circuits (PMIC), driver ICs and server ICs. However, the conventional high voltage device has the following drawback. N-type high voltage devices and P-type high voltage devices have different application scopes, with different limitations, causing difficulties in circuit designs, in particular in the application of server ICs. One attempt to solve this drawback is to couple an N-type high voltage device with a P-type high voltage device, but this will greatly increase the area size, resulting in poor utilization efficiency.

In view of the above, to overcome the drawback in the prior art, the present invention proposes an integration process, which forms a high voltage CMOS device integrating an N-type high voltage device and a P-type high voltage device therein, and a manufacturing method thereof.

### SUMMARY OF THE INVENTION

From one perspective, the present invention provides a high voltage complementary metal oxide semiconductor (CMOS) device, comprising: a semiconductor layer, which is formed on a substrate; a plurality of insulation regions, which are formed on the semiconductor layer, for defining an N-type high voltage device region and a P-type high voltage device region, wherein an N-type high voltage device is formed in the N-type high voltage device region, whereas, a P-type high voltage device is formed in the P-type high voltage device region; a first N-type high voltage well and a second N-type high voltage well, which are formed, by one same ion implantation process, in the semiconductor layer of the N-type high voltage device region and in the semiconductor layer of the P-type high voltage device region, respectively; a first P-type high voltage well and a second P-type high voltage well, which are formed, by one same ion implantation process, in the semiconductor layer of the N-type high voltage device region and in the semiconductor layer of the P-type high voltage device region, respectively, wherein the first N-type high voltage well and the first P-type high voltage well are in contact with each other in a channel direction, and wherein the second N-type high voltage well and the second P-type high voltage well are in contact with each other in the channel direction; a first drift oxide region and a second oxide region, which are formed, by one same process including etching a drift oxide layer, in the N-type high voltage device region and in the P-type high voltage device region, respectively; a first gate and a second gate, which are formed, by one same process including etching a polysilicon layer, in the N-type high voltage device region and in the P-type high voltage device region, respectively; an N-type source and an N-type drain, which are formed, by one same ion implantation process, in the semiconductor layer of the N-type high voltage device region, wherein the N-type source and the N-type drain are located below and outside two sides of the first gate, respectively, wherein a side of the first gate which is closer to the N-type source is a source side and another side of the first gate which is closer to the N-type drain is a drain side, and wherein the N-type source is located in the first P-type high voltage well, and the N-type drain is located in the first N-type high voltage well; and a P-type source and a P-type drain, which are formed, by one same ion implantation process, in the semiconductor layer of the P-type high voltage device region, wherein the P-type source and the P-type drain are located below and outside two sides of the second gate, respectively, wherein a side of the second gate which is closer to the P-type source is a source side and another side of the second gate which is closer to the P-type drain is a drain side, and wherein the P-type source is located in the second N-type high voltage well, and the P-type drain is located in the second P-type high voltage well.

From another perspective, the present invention provides a manufacturing method of a high voltage CMOS device, wherein the high voltage CMOS device includes: an N-type high voltage device and a P-type high voltage device; the manufacturing method of a high voltage CMOS device comprising following steps: forming a semiconductor layer on a substrate; forming a plurality of insulation regions on the semiconductor layer, to define an N-type high voltage device region and a P-type high voltage device region, wherein the N-type high voltage device is formed in the N-type high voltage device region, whereas, the P-type high voltage device is formed in the P-type high voltage device region; forming a first N-type high voltage well in the semiconductor layer of the N-type high voltage device region and forming a second N-type high voltage well in the semiconductor layer of the P-type high voltage device region by one same ion implantation process; forming a first P-type high voltage well in the semiconductor layer of the N-type high voltage device region and forming a second P-type high voltage well in the semiconductor layer of the P-type high voltage device region by one same ion implantation process, wherein the first N-type high voltage well and the first P-type high voltage well are in contact with each other in a channel direction, and wherein the second N-type high voltage well and the second P-type high voltage well are in contact with each other in the channel direction; forming a drift oxide layer on the semiconductor layer, wherein the drift oxide layer overlays the N-type high voltage device region and the P-type high voltage device region; etching the drift oxide layer by one same etching process, to form a first drift oxide region in the N-type high voltage device region and to form a second oxide region in the P-type high voltage device region; subsequent to the formation of the first drift oxide region and the second oxide region, forming a gate dielectric layer on the semiconductor layer, wherein the gate dielectric layer overlays the N-type high voltage device region and the P-type high voltage device region; forming a polysilicon layer on the gate dielectric layer, wherein the polysilicon layer overlays the N-type high voltage device region and the P-type high voltage device region; etching the polysilicon layer by one same etching process, to form a first gate in the N-type high voltage device region and to form a second gate in the P-type high voltage device region; forming an N-type source and an N-type drain in the semiconductor layer of the N-type high voltage device region by one same ion implantation process, wherein the N-type source and the N-type drain are located below and outside two sides of the first gate, respectively, wherein a side of the first gate which is closer to the N-type source is a source side and another side of the first gate which is closer to the N-type drain is a drain side, and wherein the N-type source is located in the first P-type high voltage well, and the N-type drain is located in the first N-type high voltage well; and forming a P-type source and a P-type drain in the semiconductor layer of the P-type high voltage device region by one same ion implantation process, wherein the P-type source and the P-type drain are located below and outside two sides of the second gate, respectively, wherein a side of the second gate which is closer to the P-type source is a source side and another side of the second gate which is closer to the P-type drain is a drain side, and wherein the P-type source is located in the second N-type high voltage well, and the P-type drain is located in the second P-type high voltage well.

In one embodiment, the high voltage CMOS device further comprises: a first shallow trench isolation (STI) region and a second STI region, which are formed, by one same process, in the N-type high voltage device region and in the P-type high voltage device region, respectively, wherein the first STI region is located vertically below and in contact with the first drift oxide region, whereas, the second STI region is located vertically below and in contact with the second drift oxide region.

In one embodiment, the high voltage CMOS device further comprises: an N-type conductive region, which is formed in the second N-type high voltage well by the one same ion implantation process that forms the N-type source and the N-type drain, wherein the N-type conductive region serves as an electrical contact of the second N-type high voltage well; and a P-type conductive region, which is formed in the first P-type high voltage well by the one same ion implantation process that forms the P-type source and the P-type drain, wherein the P-type conductive region serves as an electrical contact of the first P-type high voltage well.

In one embodiment, the high voltage CMOS device further comprises: a first N-type buried layer and a second N-type buried layer, which are formed, by one same process, in the N-type high voltage device region and in the P-type high voltage device region, respectively; wherein the first N-type buried layer is formed in and in contact with the semiconductor layer and the substrate which are vertically below the first N-type high voltage well and the first P-type high voltage well; wherein the second N-type buried layer is formed in and in contact with the semiconductor layer and the substrate which are vertically below the second N-type high voltage well and the second P-type high voltage well.

In one embodiment, the high voltage CMOS device further comprises: a first N-type high voltage isolation region and a second N-type high voltage isolation region, which are formed by the one same ion implantation process that forms the first N-type high voltage well and the second N-type high voltage well; and a first P-type high voltage isolation region and a second P-type high voltage isolation region, which are formed by the one same ion implantation process that forms the first P-type high voltage well and the second P-type high voltage well; wherein in the channel direction, the first N-type high voltage isolation region is in contact with a side of the first P-type high voltage well, wherein this side of the first P-type high voltage well is opposite to another side of the first P-type high voltage well which is in contact with the first N-type high voltage well; wherein in the channel direction, the second N-type high voltage isolation region is in contact with a side of the second P-type high voltage well, wherein this side of the second P-type high voltage well is opposite to another side of the second P-type high voltage well which is in contact with the second N-type high voltage well; wherein in the channel direction, the first P-type high voltage isolation region is in contact with a side of the first N-type high voltage well, wherein this side of the first N-type high voltage well is opposite to another side of the first N-type high voltage well which is in contact with the first P-type high voltage well; wherein in the channel direction, the second P-type high voltage isolation region is in contact with a side of the second N-type high voltage well, wherein this side of the second N-type high voltage well is opposite to another side of the second N-type high voltage well which is in contact with the second P-type high voltage well.

In one embodiment, the semiconductor layer is a P-type semiconductor epitaxial layer having a volume resistivity of 45 Ohm-cm.

In one embodiment, each of the first drift oxide region and the second oxide region has a thickness ranging between 400 Å and 450 Å.

In one embodiment, a dielectric layer of the first gate and a dielectric layer of the second gate has a thickness ranging between 80 Å and 100 Å.

In one embodiment, a gate driving voltage of the N-type high voltage device is 3.3V.

In one embodiment, the high voltage CMOS device has a minimum feature size of 0.18 micrometer.

Advantages of the present invention include: that, the present invention can form different units of the N-type high voltage device and the P-type high voltage device of the high voltage CMOS device at the same time by one same manufacturing process; and that, the present invention forms an isolation region in the semiconductor layer to electrically isolate the N-type high voltage device and the P-type high voltage device.

The objectives, technical details, features, and effects of the present invention will be better understood with regard to the detailed description of the embodiments below, with reference to the attached drawings.

### BRIEF DESCRIPTION OF THE DRAWINGS

FIG. 1 shows a cross-section view of a high voltage complementary metal oxide semiconductor (CMOS) device according to an embodiment of the present invention.

FIG. 2 shows a cross-section view of a high voltage CMOS device according to another embodiment of the present invention.

FIG. 3A to FIG. 3L show cross-section views of a manufacturing method of a high voltage CMOS device according to an embodiment of the present invention.

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

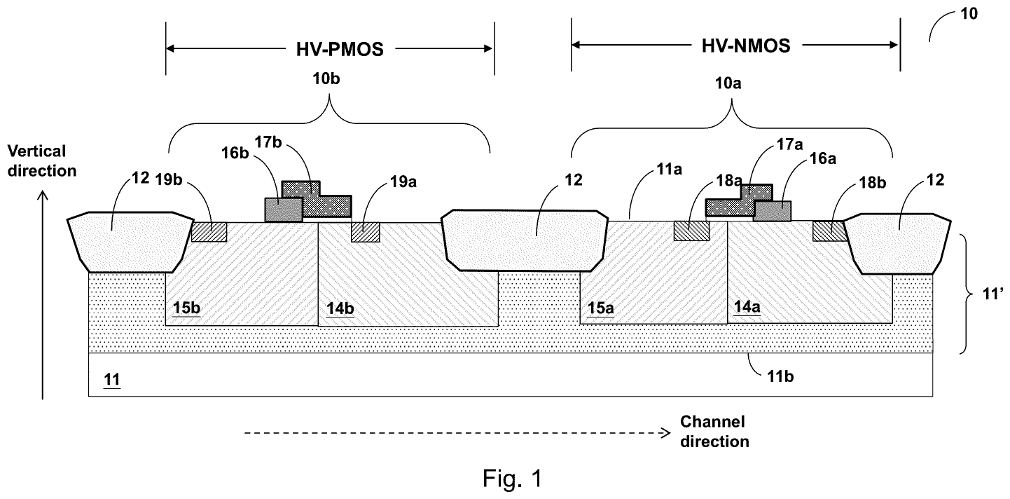

Please refer to FIG. 1, which shows a cross-section view of a high voltage complementary metal oxide semiconductor (CMOS) device 10 according to an embodiment of the present invention. As shown in FIG. 1, the high voltage CMOS device 10 comprises: a semiconductor layer 11′, insulation regions 12, a first N-type high voltage well 14a and a second N-type high voltage well 14b which are formed by one same ion implantation process, a first P-type high voltage well 15a and a second P-type high voltage well 15b which are formed by one same ion implantation process, a first drift oxide region 16a and a second oxide region 16b which are formed by one same process including etching a drift oxide layer, a first gate 17a and a second gate 17b which are formed by one same process including etching a polysilicon layer, an N-type source 18a and an N-type drain 18b, and a P-type source 19a and a P-type drain 19b.

A semiconductor layer 11′ is formed on the substrate 11. The semiconductor layer 11′ has a top surface 11a and a bottom surface 11b opposite to the top surface 11a in a vertical direction (as indicated by the direction of the solid arrow in FIG. 1, and all occurrences of the term “vertical direction” in this specification refer to the same direction). The semiconductor layer 11′, for example, is formed on the substrate 11 by an epitaxial process, or is a part of the substrate 11. The semiconductor layer 11′ can be formed by various methods known to a person having ordinary skill in the art, so the details thereof are not redundantly explained here.

Please still refer to FIG. 1. The insulation regions 12 are formed on the semiconductor layer 11′, for defining an N-type high voltage device region HV-NMOS and a P-type high voltage device region HV-PMOS, wherein an N-type high voltage device 10a is formed in the N-type high voltage device region HV-NMOS, whereas, a P-type high voltage device 10b is formed in the P-type high voltage device region HV-PMOS. The insulation regions 12 can be, for example but not limited to, a shallow trench isolation (STI) structure shown in FIG. 1.

In this embodiment, the N-type high voltage device 10a includes: the first N-type high voltage well 14a, the first P-type high voltage well 15a, the first drift oxide region 16a, the first gate 17a, the N-type source 18a and the N-type drain 18b. The P-type high voltage device 10b includes: the second N-type high voltage well 14b, the second P-type high voltage well 15b, the second oxide region 16b, the second gate 17b, the P-type source 19a and the P-type drain 19b.

Please still refer to FIG. 1. The first N-type high voltage well 14a and the second N-type high voltage well 14b, are formed by one same ion implantation process, in the semiconductor layer 11′ of the N-type high voltage device region HV-NMOS and in the semiconductor layer 11′ of the P-type high voltage device region HV-PMOS, respectively. The first N-type high voltage well 14a and the second N-type high voltage well 14b are located below and in contact with the top surface 11a in the vertical direction. A part of the first N-type high voltage well 14a is located vertically below and in contact with the gate 17a, which serve as a drift current channel in an ON operation of the N-type high voltage device 10a. Besides, a part of the second N-type high voltage well 14b is located vertically below the gate 17b, which serve as an inversion current channel in an ON operation of the P-type high voltage device 10b.

Please still refer to FIG. 1. The first P-type high voltage well 15a and the second P-type high voltage well 15b are formed by one same ion implantation process in the semiconductor layer 11′ of the N-type high voltage device region HV-NMOS and in the semiconductor layer 11′ of the P-type high voltage device region HV-PMOS, respectively, wherein the first N-type high voltage well 14a and the first P-type high voltage well 15a are in contact with each other in a channel direction (as indicated by the direction of the dashed arrow shown in FIG. 1, and all occurrences of the term “channel direction” in this specification refer to the same direction), and wherein the second N-type high voltage well 14b and the second P-type high voltage well 15b are in contact with each other in the channel direction.

Both the first P-type high voltage well 15a and the second P-type high voltage well 15b are located below and in contact with the top surface 11a. A part of the first P-type high voltage well 15a is located vertically below and in contact with the gate 17a, which serve as an inversion current channel in an ON operation of the N-type high voltage device 10a. Besides, a part of the second P-type high voltage well 15b is located vertically below the gate 17b, which serve as a drift current channel in an ON operation of the P-type high voltage device 10b.

The first drift oxide region 16a and the second oxide region 16b are formed, by one same process including etching a drift oxide layer, in the N-type high voltage device region HV-NMOS and in the P-type high voltage device region HV-PMOS, respectively. The first drift oxide region 16a and the second oxide region 16b are formed on the semiconductor layer 11′, and are located a drift region of the N-type high voltage device 10a and a drift region of the P-type high voltage device 10b, respectively.

The first gate 17a and the second gate 17b are formed, by one same process including etching a polysilicon layer, in the N-type high voltage device region HV-NMOS and in the P-type high voltage device region HV-PMOS, respectively.

The first gate 17a and the second gate 17b are formed on the top surface 11a of the semiconductor layer 11′. Each of the first gate 17a and the second gate 17b includes: a conductive layer, a spacer layer and a dielectric layer, wherein the dielectric layer is located on and in contact with the top surface 11a, which is known to a person having ordinary skill in the art, so the details thereof are not redundantly explained here.

The N-type source 18a and the N-type drain 18b are formed, by one same ion implantation process, in the semiconductor layer 11′ of the N-type high voltage device region HV-NMOS, wherein the N-type source 18a and the N-type drain 18b are located below and outside two sides of the first gate 17a in the channel direction, respectively, wherein the side of the first gate 17a which is closer to the N-type source 18a is a source side and the side of the first gate 17a which is closer to the N-type drain 18b is a drain side, and wherein the N-type source 18a is located in the first P-type high voltage well 15a, and the N-type drain 18b is located in the first N-type high voltage well 14a.

In the vertical direction, the N-type source 18a and the N-type drain 18b are formed below and in contact with the top surface 11a. And, in the channel direction, the drift region of the N-type high voltage device 10a is located between the N-type drain 18b and the first P-type high voltage well 15a, so as to separate the N-type drain 18b from the first P-type high voltage well 15a. And, a portion of the first N-type high voltage well 14a which is near the top surface 11a serves as a drift current channel in an ON operation of the N-type high voltage device 10a.

The P-type source 19a and the P-type drain 19b are formed, by one same ion implantation process, in the semiconductor layer 11′ of the P-type high voltage device region HV-PMOS, wherein the P-type source 19a and the P-type drain 19b are located below and outside two sides of the second gate 17b in the channel direction, respectively, wherein the side of the second gate 17b which is closer to the P-type source 19a is a source side and the side of the second gate 17b which is closer to the P-type drain 19b is a drain side, and wherein the P-type source 19a is located in the second N-type high voltage well 14b, and the P-type drain 19b is located in the second P-type high voltage well 15b.

In the vertical direction, the P-type source 19a and the P-type drain 19b are formed below and in contact with the top surface 11a. And, in the channel direction, the drift region of the P-type high voltage device 10b is located between the P-type drain 19b and the second N-type high voltage well 14b, so as to separate the P-type drain 18b from the second P-type high voltage well 14b. And, a portion of the second P-type high voltage well 15b which is near the top surface 11a serves as a drift current channel in an ON operation of the P-type high voltage device 10b.

In one embodiment, the semiconductor layer 11′ is a P-type semiconductor epitaxial layer having a volume resistivity of 45 Ohm-cm.

In one embodiment, each of the first drift oxide region 16a and the second drift oxide region 16b is a chemical vapor deposition (CVD) oxide region.

In one embodiment, each of the first drift oxide region 16a and the second drift oxide region 16b has a thickness ranging between 400 Å to 450 Å

In one embodiment, a dielectric layer of the first gate 17a and a dielectric layer of the second gate 17b has a thickness ranging between 80 Å to 100 Å

In one embodiment, the gate driving voltage of the N-type high voltage device 10a in the N-type high voltage device region HV-NMOS is 3.3V.

In one embodiment, the high voltage CMOS device has a minimum feature size of 0.18 micrometer (μm).

Note that the term “inversion current channel” means thus. Taking this embodiment as an example, when the N-type high voltage device 10a/the P-type high voltage device 10b operates in ON operation due to the voltage applied to the gate 17a/the gate 17b, an inversion layer is formed below the gate 17a/the gate 17b, so that a conduction current flows through the region of the inversion layer, which is the inverse current channel known to a person having ordinary skill in the art, so the details thereof are not redundantly explained here.

Note that the term “drift current channel” means thus. Taking this embodiment as an example, the drift region provides a region where the conduction current passes through in a drifting manner when the N-type high voltage device 10a/the P-type high voltage device 10b operates in the ON operation, and the current path through the drift region is referred to as the “drift current channel”, which is known to a person having ordinary skill in the art, so the details thereof are not redundantly explained here.

Note that the top surface 11a as referred to does not mean a completely flat plane but refers to the surface of the semiconductor layer 11′. In the present embodiment, for example, a part of the top surface 11a where the insulation region 12 is in contact with has a recessed portion.

Note that the term “gate” in the definition of this specification refers to a semiconductor structure which includes a conductive layer, a dielectric layer, and a spacer layer. More specifically, each of the gate 17a and the gate 17b includes a conductive layer, a dielectric layer in contact with the top surface 11a, and a spacer layer which is electrically insulative. The conductive layer serves as an electrical contact of the corresponding gate 17a or the corresponding gate 17b, and is formed on and is in contact with the dielectric layer. The spacer layer is formed out of two sides of the conductive layer, as an electrical insulative layer of the corresponding gate 17a or the corresponding gate 17b. A transistor gate is known to a person having ordinary skill in the art, so the details thereof are not redundantly explained here.

Note that the above-mentioned “N-type” and “P-type” mean that impurities of corresponding conductivity types are doped in regions of the high voltage CMOS device (for example but not limited to the aforementioned first N-type high voltage well 14a and second N-type high voltage well 14b, the aforementioned first P-type high voltage well 15a and second N-type high voltage well 15b, the aforementioned N-type source 18a and N-type drain 18b, and the aforementioned P-type source 19a and P-type drain 19b, etc.), so that the regions have the corresponding “N-type” or “P-type”, wherein “N-type” has conductivity type opposite to “P-type”.

In addition, the term “high voltage CMOS device” refers to a transistor device wherein a lateral length of the drift region is determined according to an operation voltage that the high voltage CMOS device is required to withstand in a normal operation, so that the high voltage CMOS device can operate at a predetermined high voltage which is higher than a low voltage device, which is known to a person having ordinary skill in the art, so the details thereof are not redundantly explained here.

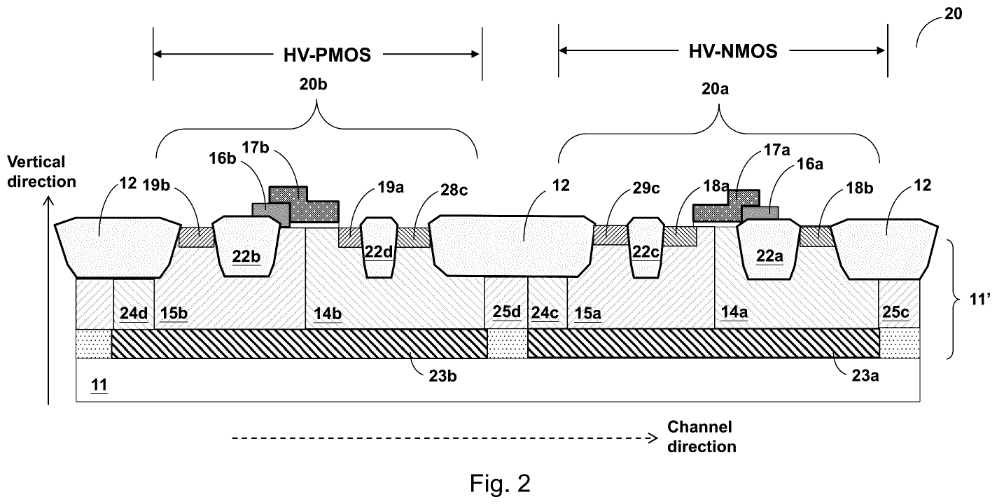

Please refer to FIG. 2, which shows a cross-section view of a high voltage CMOS device 20 according to another embodiment of the present invention. This embodiment shown in FIG. 2 is different from the embodiment shown in FIG. 1 in that: the high voltage CMOS device 20 of this embodiment further comprises a first STI region 22a, a second STI region 22b, a third STI region 22c, a fourth STI region 22d, an N-type conductive region 29c, a P-type conductive region 28c, a first N-type buried layer 23a, a second N-type buried layer 23b, a first N-type high voltage isolation region 24c, a second N-type high voltage isolation region 24d, a first P-type high voltage isolation region 25c and a second P-type high voltage isolation region 25d.

The first STI region 22a, the second STI region 22b, the third STI region 22c and the fourth STI region 22d are formed by one same process that forms the isolation regions 12. The first STI region 22a and the third STI region 22c are formed in the N-type high voltage device region HV-NMOS, whereas, the second STI region 22b and the fourth STI region 22d are formed in the P-type high voltage device region HV-PMOS. The first STI region 22a is located vertically below and in contact with the first drift oxide region 16a, whereas, the second STI region 22b is located vertically below and in contact with the second drift oxide region 16b.

In the semiconductor layer 11′, the third STI region 22c serves to electrically isolate the N-type source 18a from the P-type conductive region 28c. In the semiconductor layer 11′, the fourth STI region 22d serves to electrically isolate the P-type source 19a from the N-type conductive region 29c.

P-type conductive region 28c is formed in the semiconductor layer 11′ of the P-type high voltage device region HV-PMOS by the one same ion implantation process that forms the P-type source 19a and the P-type drain 19b, wherein the P-type conductive region 28c serves as an electrical contact of the first P-type high voltage well 15a.

The N-type conductive region 29c is formed in the semiconductor layer 11′ of the N-type high voltage device region HV-NMOS by the one same ion implantation process that forms the N-type source 18a and the N-type drain 18b, wherein the N-type conductive region 29c serves as an electrical contact of the second N-type high voltage well 14b.

The first N-type buried layer 23a and the second N-type buried layer 23b are formed, by one same process, in the N-type high voltage device region HV-NMOS and in the P-type high voltage device region HV-PMOS, respectively. The first N-type buried layer 23a is formed in and in contact with the semiconductor layer 11′ and the substrate 11 which are vertically below the first N-type high voltage well 14a and the first P-type high voltage well 15a.

The first N-type high voltage isolation region 24c and the second N-type high voltage isolation region 24d are formed by the one same ion implantation process that forms the first N-type high voltage well 14a and the second N-type high voltage well 14b. The first P-type high voltage isolation region 25c and the second P-type high voltage isolation region 25d are formed by the one same ion implantation process that forms the first P-type high voltage well 15a and the second P-type high voltage well 15b.

In the channel direction, the first N-type high voltage isolation region 24C is in contact with a side of the first P-type high voltage well 15a, wherein this side of the first P-type high voltage well 15a is opposite to another side of the first P-type high voltage well 15a which is in contact with the first N-type high voltage well 14a. In the channel direction, the second N-type high voltage isolation region 24d is in contact with a side of the second P-type high voltage well 15b, wherein this side of the second P-type high voltage well 15b is opposite to another side of the second P-type high voltage well 15b which is in contact with the second N-type high voltage well 14b. In the channel direction, the first P-type high voltage isolation region 25c is in contact with a side of the first N-type high voltage well 14a, wherein this side of the first N-type high voltage well 14a is opposite to another side of the first N-type high voltage well 14a which is in contact with the first P-type high voltage well 15a. In the channel direction, the second P-type high voltage isolation region 25d is in contact with a side of the second N-type high voltage well 14b, wherein this side of the second N-type high voltage well 14b is opposite to another side of the second N-type high voltage well 14b which is in contact with the second P-type high voltage well 15b.

In the semiconductor layer 11′, the first N-type buried layer 23a, the first N-type high voltage isolation region 24c and the first P-type high voltage isolation region 25c encloses a boundary of the N-type high voltage device 20a, so as to electrically isolate the N-type high voltage device 20a. The second N-type buried layer 23b, the second N-type high voltage isolation region 24d and the second P-type high voltage isolation region 25d encloses a boundary of the P-type high voltage device 20b, so as to electrically isolate the P-type high voltage device 20b.

The first N-type buried layer 23a and the second N-type buried layer 23b can be formed by, for example but not limited to, an ion implantation process, which implants N conductivity type impurities into the substrate 11 in the form of accelerated ions. Next, during or subsequent to the formation of the semiconductor layer 11′, the first N-type buried layer 23a and the second N-type buried layer 23b are formed by thermal diffusion.

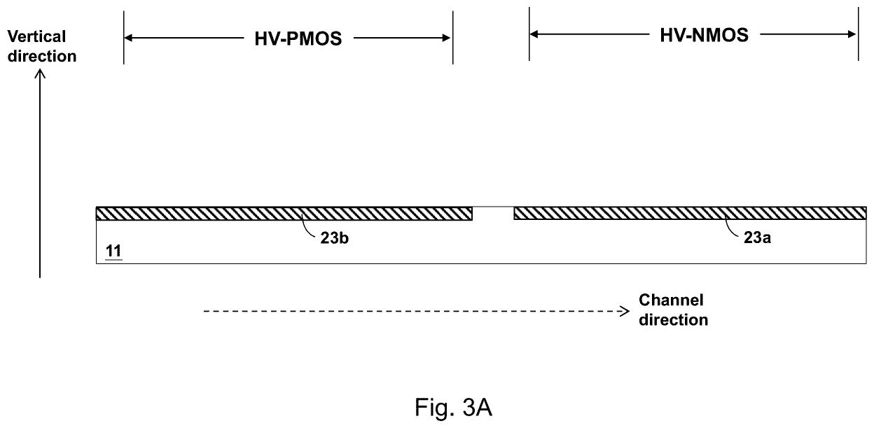

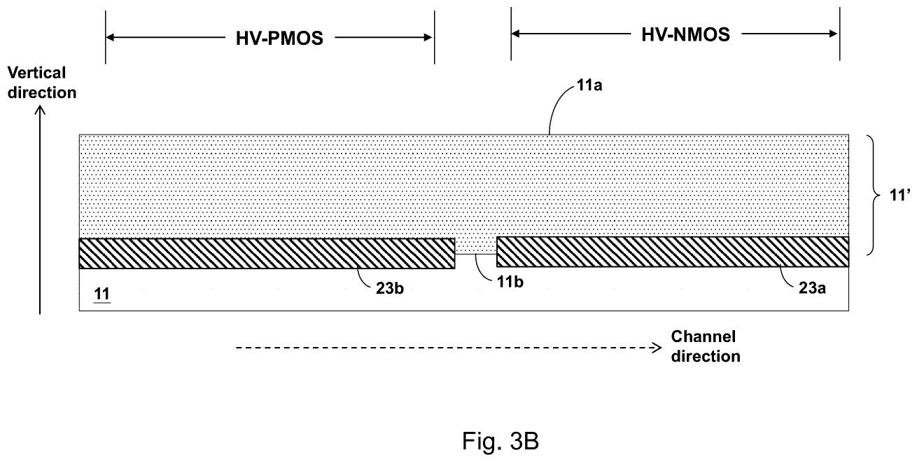

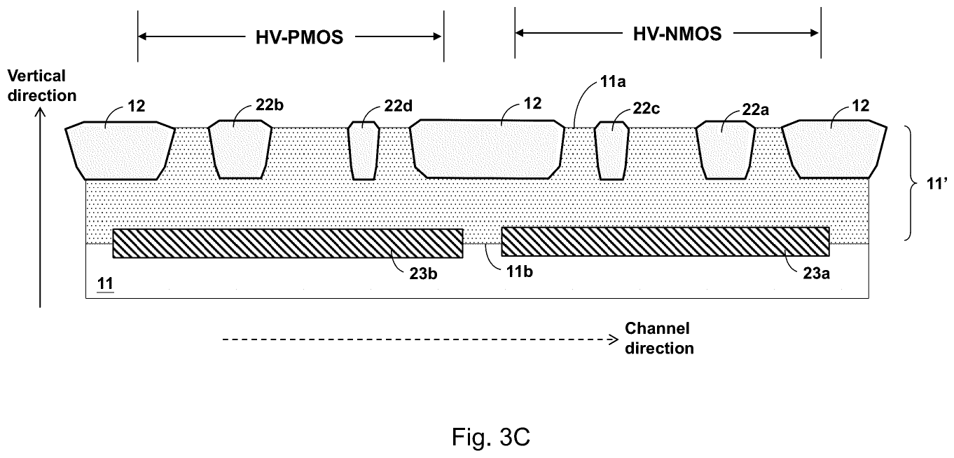

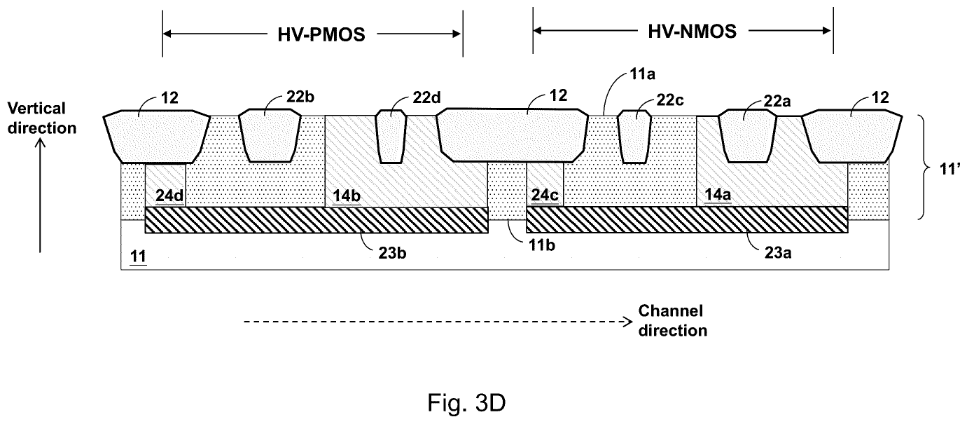

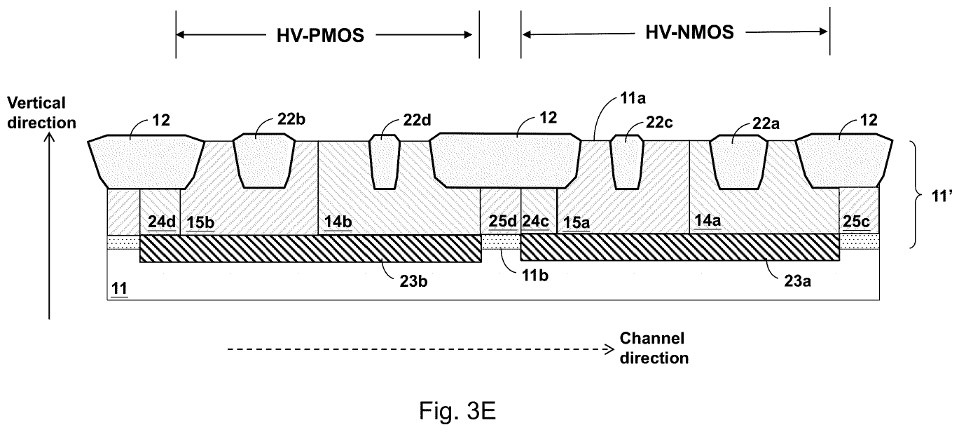

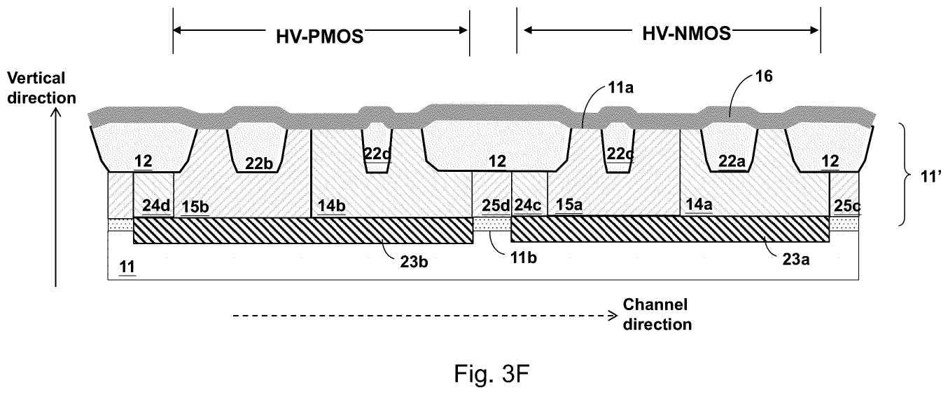

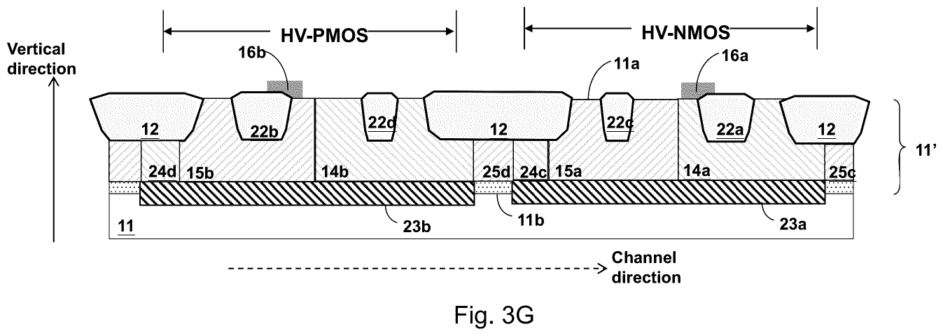

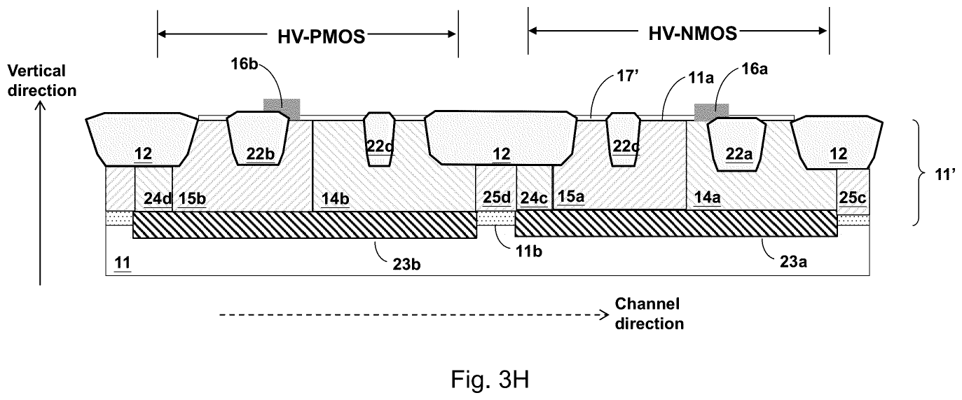

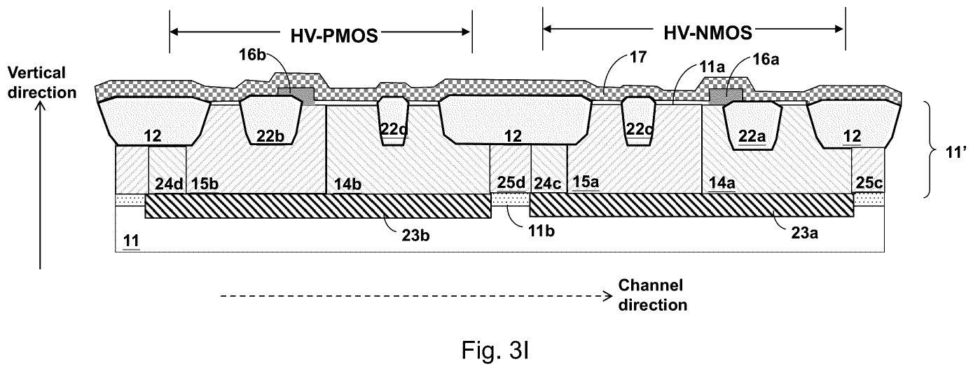

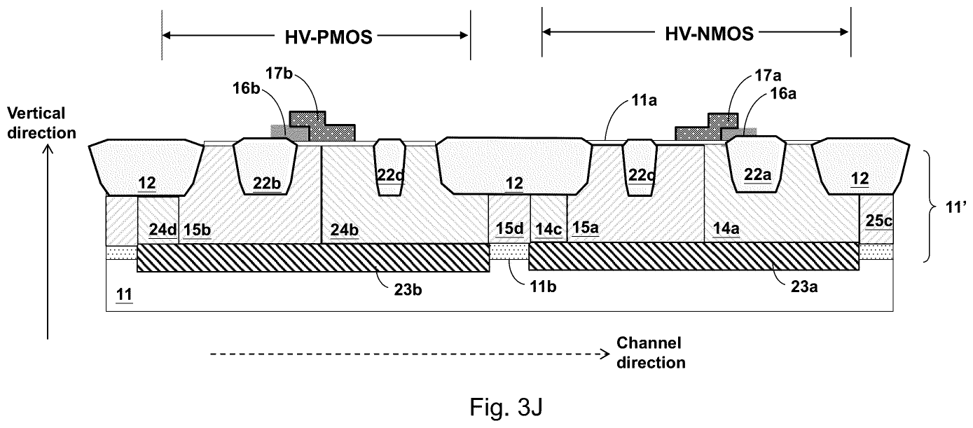

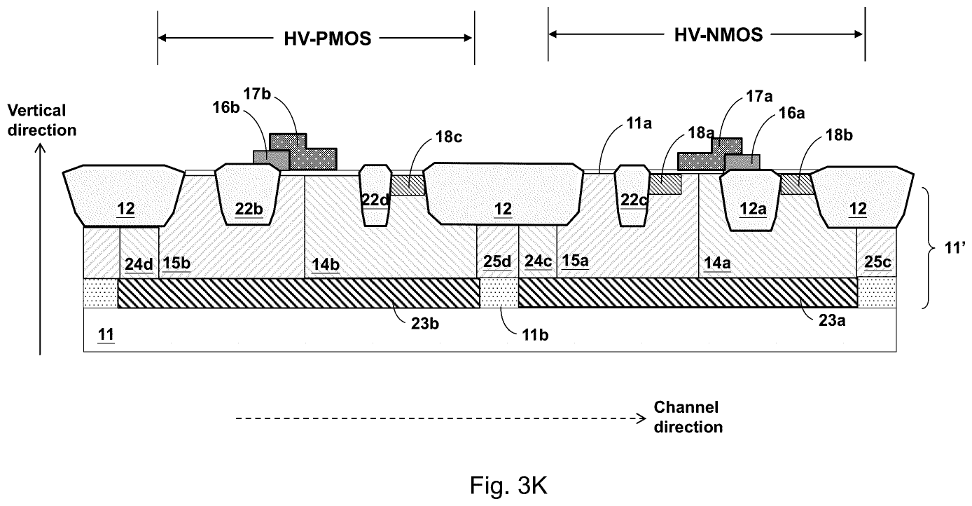

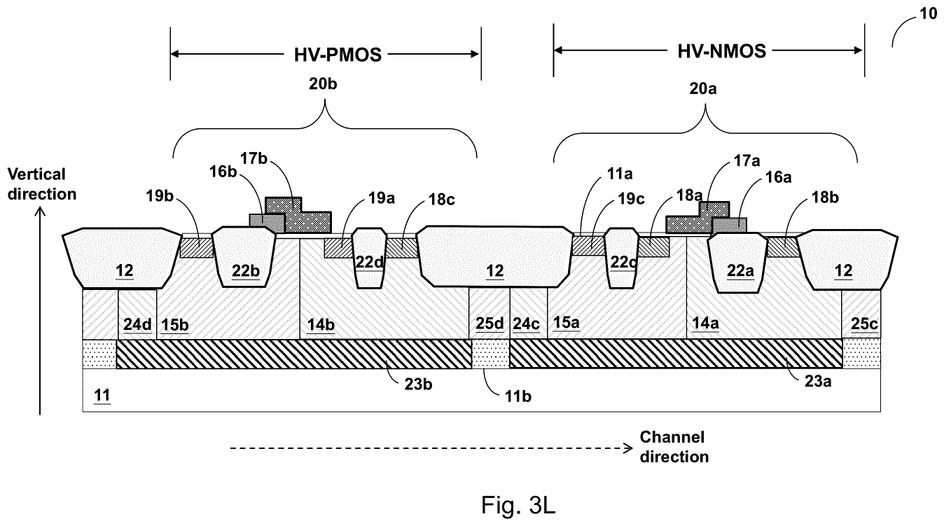

Please refer to FIG. 3A to FIG. 3L, which show a cross-section view of a manufacturing method of a high voltage CMOS device 20 according to an embodiment of the present invention. The high voltage CMOS device 20 includes: an N-type high voltage device 20a and a P-type high voltage device 20b. As shown in FIG. 3A, a substrate 11 is provided. And, a first N-type buried layer 23a and a second N-type buried layer 23b are formed by, for example but not limited to, an ion implantation process, which implants N conductivity type impurities into the substrate 11 in the form of accelerated ions. Later, during or subsequent to the formation of a semiconductor layer 11′ (as shown in FIG. 3B), the first N-type buried layer 23a and the second N-type buried layer 23b are subject to thermal diffusion to be completely formed.

Next, referring to FIG. 3B, the semiconductor layer 11′ is formed on the substrate 11. The semiconductor layer 11′ is formed on the substrate 11 for example by an epitaxial process, or is a part of the substrate 11. As described above, during or subsequent to the formation of the semiconductor layer 11′, the first N-type buried layer 23a and the second N-type buried layer 23b thermally diffuse to be completely formed. The semiconductor layer 11′ has a top surface 11a and a bottom surface 11b opposite to the top surface 11a in the vertical direction (as indicated by the direction of the solid arrow in FIG. 3B). The semiconductor layer 11′ can be formed by various methods known to a person having ordinary skill in the art, so the details thereof are not redundantly explained here. The substrate 11 can be for example a P-type or an N-type semiconductor substrate.

Next, referring to FIG. 3C, the isolation regions 12, the first STI region 22a, the second STI region 22b, the third STI region 22c and the fourth STI region 22d are formed by for example one same process. The isolation regions 12, the first STI region 22a, the second STI region 22b, the third STI region 22c and the fourth STI region 22d can be for example but not limited to a shallow trench isolation (STI) structure.

The insulation regions 12 are formed on the semiconductor layer 11′, for defining an N-type high voltage device region HV-NMOS and a P-type high voltage device region HV-PMOS, wherein an N-type high voltage device 20a is formed in the N-type high voltage device region HV-NMOS, whereas, a P-type high voltage device 20b is formed in the P-type high voltage device region HV-PMOS. The first STI region 22a and the third STI region 22c are formed in the N-type high voltage device region HV-NMOS, whereas, the second STI region 22b and the fourth STI region 22d are formed in the P-type high voltage device region HV-PMOS. The first STI region 22a is located vertically below and in contact with the first drift oxide region 16a, whereas, the second STI region 22b is located vertically below and in contact with the second drift oxide region 16b. In the semiconductor layer 11′, the third STI region 22c serves to electrically isolate the N-type source 18a from the P-type conductive region 28c. In the semiconductor layer 11′, the fourth STI region 22d serves to electrically isolate the P-type source 19a from the N-type conductive region 29c.

Next, referring to FIG. 3D, the first N-type high voltage well 14a, the second N-type high voltage well 14b, the first N-type high voltage isolation region 24c, and the second N-type high voltage isolation region 24d are formed by one same ion implantation process.

The first N-type high voltage well 14a and the second N-type high voltage well 14b are formed in the semiconductor layer 11′ of the N-type high voltage device region HV-NMOS and in the semiconductor layer 11′ of the P-type high voltage device region HV-PMOS, respectively. The first N-type high voltage well 14a and the second N-type high voltage well 14b are located below and in contact with the top surface 11a in the vertical direction. A part of the first N-type high voltage well 14a is located vertically below and in contact with the gate 17a, which serve as a drift current channel in an ON operation of the N-type high voltage device 10a. Besides, a part of the second N-type high voltage well 14b is located vertically below the gate 17b, which serve as an inversion current channel in an ON operation of the P-type high voltage device 10b.

In the channel direction, the first N-type high voltage isolation region 24C is in contact with a side of the first P-type high voltage well 15a, wherein this side of the first P-type high voltage well 15a is opposite to another side of the first P-type high voltage well 15a which is in contact with the first N-type high voltage well 14a. In the channel direction, the second N-type high voltage isolation region 24d is in contact with a side of the second P-type high voltage well 15b, wherein this side of the second P-type high voltage well 15b is opposite to another side of the second P-type high voltage well 15b which is in contact with the second N-type high voltage well 14b.

Next, referring to FIG. 3E, the first P-type high voltage well 15a, the second P-type high voltage well 15b, the first P-type high voltage isolation region 25c and the second P-type high voltage isolation region 25d are formed by one same ion implantation process.

The first P-type high voltage well 15a and the second P-type high voltage well 15b are formed by one same ion implantation process in the semiconductor layer 11′ of the N-type high voltage device region HV-NMOS and in the semiconductor layer 11′ of the P-type high voltage device region HV-PMOS, respectively, wherein the first N-type high voltage well 14a and the first P-type high voltage well 15a are in contact with each other in the channel direction, and wherein the second N-type high voltage well 14b and the second P-type high voltage well 15b are in contact with each other in the channel direction.

Both the first P-type high voltage well 15a and the second P-type high voltage well 15b are located below and in contact with the top surface 11a. A part of the first P-type high voltage well 15a is located vertically below and in contact with the gate 17a, which serve as an inversion current channel in an ON operation of the N-type high voltage device 10a. Besides, a part of the second P-type high voltage well 15b is located vertically below the gate 17b, which serve as a drift current channel in an ON operation of the P-type high voltage device 10b.

In the channel direction, the first P-type high voltage isolation region 25c is in contact with a side of the first N-type high voltage well 14a, wherein this side of the first N-type high voltage well 14a is opposite to another side of the first N-type high voltage well 14a which is in contact with the first P-type high voltage well 15a. In the channel direction, the second P-type high voltage isolation region 25d is in contact with a side of the second N-type high voltage well 14b, wherein this side of the second N-type high voltage well 14b is opposite to another side of the second N-type high voltage well 14b which is in contact with the second P-type high voltage well 15b.

In the semiconductor layer 11′, the first N-type buried layer 23a, the first N-type high voltage isolation region 24c and the first P-type high voltage isolation region 25c encloses a boundary of the N-type high voltage device 20a, so as to electrically isolate the N-type high voltage device 20a. The second N-type buried layer 23b, the second N-type high voltage isolation region 24d and the second P-type high voltage isolation region 25d encloses a boundary of the P-type high voltage device 20b, so as to electrically isolate the P-type high voltage device 20b.

Next, referring to FIG. 3F, a drift oxide layer 16 is formed on the semiconductor layer 11′ by for example but not limited to a deposition process, wherein the drift oxide layer 16 overlays the N-type high voltage device region HV-NMOS and the P-type high voltage device region HV-PMOS.

Next, referring to FIG. 3G, by one same etching process, the drift oxide layer 16 is etched to form a first drift oxide region 16a in the N-type high voltage device region HV-NMOS and to form a second oxide region 16b in the P-type high voltage device region HV-PMOS. The first drift oxide region 16a and the second oxide region 16b are formed on the semiconductor layer 11′, and are located on a drift region of the N-type high voltage device 10a and a drift region of the P-type high voltage device 10b, respectively.

Next, referring to FIG. 3H, subsequent to the formation of the first drift oxide region 16a and the second oxide region 16b, a gate dielectric layer 17′ is formed on the semiconductor layer 11′, wherein the gate dielectric layer 17′ overlays the N-type high voltage device region HV-NMOS and the P-type high voltage device region HV-PMOS.

Next, referring to FIG. 3I, subsequent to the formation of the gate dielectric layer 17′, a polysilicon layer 17 is formed on the gate dielectric layer 17′ by for example but not limited to a deposition process, wherein the polysilicon layer 17 overlays the N-type high voltage device region HV-NMOS and the P-type high voltage device region HV-PMOS.

Next, referring to FIG. 3J, subsequent to the formation of the polysilicon layer 17, by one same etching process, the polysilicon layer 17 is etched to form a first gate 17a in the N-type high voltage device region HV-NMOS and to form a second gate 17b in the P-type high voltage device region HV-PMOS.

Note that the thickness of the gate dielectric layer 17′ is significantly thinner than the thickness of the polysilicon layer 17. The gate dielectric layer 17′ serves to function as a dielectric layer of the first gate 17a and a dielectric layer of the second gate 17b, which is known to a person having ordinary skill in the art, so the details thereof are not redundantly explained here.

The first gate 17a and the second gate 17b are formed on the top surface 11a of the semiconductor layer 11′. Each of the first gate 17a and the second gate 17b includes: a conductive layer, a spacer layer and a dielectric layer, wherein the dielectric layer is located on and in contact with the top surface 11a, which is known to a person having ordinary skill in the art, so the details thereof are not redundantly explained here.

Next, referring to FIG. 3K, the N-type source 18a and the N-type drain 18b and the N-type conductive region 29c are formed by one same ion implantation process. The N-type source 18a and the N-type drain 18b are formed in the semiconductor layer 11′ of the N-type high voltage device region HV-NMOS, wherein the N-type source 18a and the N-type drain 18b are located below and outside two sides of the first gate 17a in the channel direction, respectively, wherein the side of the first gate 17a which is closer to the N-type source 18a is a source side and the side of the first gate 17a which is closer to the N-type drain 18b is a drain side, and wherein the N-type source 18a is located in the first P-type high voltage well 15a, and the N-type drain 18b is located in the first N-type high voltage well 14a.

In the vertical direction, the N-type source 18a and the N-type drain 18b are formed below and in contact with the top surface 11a. And, in the channel direction, the drift region of the N-type high voltage device 10a is located between the N-type drain 18b and the first P-type high voltage well 15a, so as to separate the N-type drain 18b from the first P-type high voltage well 15a. And, a portion of the first N-type high voltage well 14a which is near the top surface 11a serves as a drift current channel in an ON operation of the N-type high voltage device 10a.

The N-type conductive region 29c is formed in the semiconductor layer 11′ of the P-type high voltage device region HV-PMOS, wherein the N-type conductive region 29c serves as an electrical contact of the second N-type high voltage well 14b.

Next, referring to FIG. 3L, the P-type source 19a, the P-type drain 19b and the P-type conductive region 28c are formed by one same ion implantation process. The P-type source 19a and the P-type drain 19b are formed in the semiconductor layer 11′ of the P-type high voltage device region HV-PMOS, wherein the P-type source 19a and the P-type drain 19b are located below and outside two sides of the second gate 17b in the channel direction, respectively, wherein the side of the second gate 17b which is closer to the P-type source 19a is a source side and the side of the second gate 17b which is closer to the P-type drain 19b is a drain side, and wherein the P-type source 19a is located in the second N-type high voltage well 14b, and the P-type drain 19b is located in the second P-type high voltage well 15b.

In the vertical direction, the P-type source 19a and the P-type drain 19b are formed below and in contact with the top surface 11a. And, in the channel direction, the drift region of the P-type high voltage device 10b is located between the P-type drain 19b and the second N-type high voltage well 14b, so as to separate the P-type drain 18b from the second P-type high voltage well 14b. And, a portion of the second P-type high voltage well 15b which is near the top surface 11a serves as a drift current channel in an ON operation of the P-type high voltage device 10b.

The P-type conductive region 28c is formed in the semiconductor layer 11′ of the P-type high voltage device region HV-NMOS, wherein the P-type conductive region 28c serves as an electrical contact of the first N-type high voltage well 15a.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, other process steps or structures, such as a lightly doped drain (LDD) may be added. For another example, the lithography process is not limited to the mask technology but it can also include electron beam lithography. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A manufacturing method of a high voltage CMOS device, wherein the high voltage CMOS device includes: an N-type high voltage device and a P-type high voltage device; the manufacturing method of a high voltage CMOS device comprising steps of:
forming a semiconductor layer on a substrate;
forming a plurality of insulation regions on the semiconductor layer, to define an N-type high voltage device region and a P-type high voltage device region, wherein the N-type high voltage device is formed in the N-type high voltage device region, whereas, the P-type high voltage device is formed in the P-type high voltage device region;
forming a first N-type high voltage well in the semiconductor layer of the N-type high voltage device region and forming a second N-type high voltage well in the semiconductor layer of the P-type high voltage device region by one same ion implantation process;
forming a first P-type high voltage well in the semiconductor layer of the N-type high voltage device region and forming a second P-type high voltage well in the semiconductor layer of the P-type high voltage device region by one same ion implantation process, wherein the first N-type high voltage well and the first P-type high voltage well are in contact with each other in a channel direction, and wherein the second N-type high voltage well and the second P-type high voltage well are in contact with each other in the channel direction;
forming a drift oxide layer on the semiconductor layer, wherein the drift oxide layer overlays the N-type high voltage device region and the P-type high voltage device region;
etching the drift oxide layer by one same etching process, to form a first drift oxide region in the N-type high voltage device region and to form a second oxide region in the P-type high voltage device region;
subsequent to the formation of the first drift oxide region and the second oxide region, forming a gate dielectric layer on the semiconductor layer, wherein the gate dielectric layer overlays the N-type high voltage device region and the P-type high voltage device region;
forming a polysilicon layer on the gate dielectric layer, wherein the polysilicon layer overlays the N-type high voltage device region and the P-type high voltage device region;
etching the polysilicon layer by one same etching process, to form a first gate in the N-type high voltage device region and to form a second gate in the P-type high voltage device region;
forming an N-type source and an N-type drain in the semiconductor layer of the N-type high voltage device region by one same ion implantation process, wherein the N-type source and the N-type drain are located below and outside two sides of the first gate, respectively, wherein a side of the first gate which is closer to the N-type source is a source side and another side of the first gate which is closer to the N-type drain is a drain side, and wherein the N-type source is located in the first P-type high voltage well, and the N-type drain is located in the first N-type high voltage well; and
forming P-type source and a P-type drain in the semiconductor layer of the P-type high voltage device region by one same ion implantation process, wherein the P-type source and the P-type drain are located below and outside two sides of the second gate, respectively, wherein a side of the second gate which is closer to the P-type source is a source side and another side of the second gate which is closer to the P-type drain is a drain side, and wherein the P-type source is located in the second N-type high voltage well, and the P-type drain is located in the second P-type high voltage well.

2. The manufacturing method of the high voltage CMOS device of claim 1, further comprising:
forming a first STI region in the N-type high voltage device region and forming a second STI region in the P-type high voltage device region by one same process, wherein the first STI region is located vertically below and in contact with the first drift oxide region, whereas, the second STI region is located vertically below and in contact with the second drift oxide region.

3. The manufacturing method of the high voltage CMOS device of claim 1, further comprising:
forming an N-type conductive region in the second N-type high voltage well by the one same ion implantation process that forms the N-type source and the N-type drain, wherein the N-type conductive region serves as an electrical contact of the second N-type high voltage well; and
forming a P-type conductive region in the first P-type high voltage well by the one same ion implantation process that forms the P-type source and the P-type drain, wherein the P-type conductive region serves as an electrical contact of the first P-type high voltage well.

4. The manufacturing method of the high voltage CMOS device of claim 1, further comprising:
forming a first N-type buried layer and a second N-type buried layer by one same process, wherein the first N-type buried layer is in the N-type high voltage device region and the second N-type buried layer is in the P-type high voltage device region;
wherein the first N-type buried layer is formed in and in contact with the semiconductor layer and the substrate which are vertically below the first N-type high voltage well and the first P-type high voltage well;
wherein the second N-type buried layer is formed in and in contact with the semiconductor layer and the substrate which are vertically below the second N-type high voltage well and the second P-type high voltage well.

5. The manufacturing method of the high voltage CMOS device of claim 1, further comprising:
forming a first N-type high voltage isolation region and a second N-type high voltage isolation region by the one same ion implantation process that forms the first N-type high voltage well and the second N-type high voltage well;
forming a first P-type high voltage isolation region and a second P-type high voltage isolation region by the one same ion implantation process that forms the first P-type high voltage well and the second P-type high voltage well;
wherein in the channel direction, the first N-type high voltage isolation region is in contact with a side of the first P-type high voltage well, wherein this side of the first P-type high voltage well is opposite to another side of the first P-type high voltage well which is in contact with the first N-type high voltage well;
wherein in the channel direction, the second N-type high voltage isolation region is in contact with a side of the second P-type high voltage well, wherein this side of the second P-type high voltage well is opposite to another side of the second P-type high voltage well which is in contact with the second N-type high voltage well;
wherein in the channel direction, the first P-type high voltage isolation region is in contact with a side of the first N-type high voltage well, wherein this side of the first N-type high voltage well is opposite to another side of the first N-type high voltage well which is in contact with the first P-type high voltage well;
wherein in the channel direction, the second P-type high voltage isolation region is in contact with a side of the second N-type high voltage well, wherein this side of the second N-type high voltage well is opposite to another side of the second N-type high voltage well which is in contact with the second P-type high voltage well.

6. The manufacturing method of the high voltage CMOS device of claim 1, wherein the semiconductor layer is a P-type semiconductor epitaxial layer having a volume resistivity of 45 Ohm-cm.

7. The manufacturing method of the high voltage CMOS device of claim 1, wherein each of the first drift oxide region and the second oxide region has a thickness ranging between 400 Å and 450 Å.

8. The manufacturing method of the high voltage CMOS device of claim 1, wherein a dielectric layer of the first gate and a dielectric layer of the second gate has a thickness ranging between 80 Å and 100 Å.

9. The manufacturing method of the high voltage CMOS device of claim 1, wherein a gate driving voltage of the N-type high voltage device is 3.3V.

10. The manufacturing method of the high voltage CMOS device of claim 1, wherein the high voltage CMOS device has a minimum feature size of 0.18 micrometer (μm).
